(19) United States
(12) Patent Application Publication
(10) Pub. No.: US 2006/0061349 A1
(43) Pub. Date: Mar. 23, 2006

(54) Versatile system for time-independent signal sampling

(76) Inventor: David W. Guidry, Rowlett, TX (US)

Correspondence Address: TEXAS INSTRUMENTS INCORPORATED, P O BOX 655474, M/S 3999, DALLAS, TX, 75265, US

(21) Appl. No.: 10/946,661

(22) Filed: Sep. 22, 2004

(51) Int. Cl. G01R 13/02

(52) U.S. Cl. 324/76.47

(57) ABSTRACT

The present invention provides a system (100) that overcomes performance incongruities between a high-speed device (102) and commercial ATE (106). The system of the present invention provides an analog-to-analog sampler (104), having a clock input (118). The analog-to-analog sampler receives a first analog test signal (108) from the high-speed device, and converts it into a second analog test signal (116) at a desired rate, utilizing an analog-to-digital-to-analog conversion function (112) and a decimation function (114). The ATE system houses an analog capture component (120). The analog capture component has a clock input (122), and receives the second analog test signal for conversion into digital format. A series of clock signals (126) are generated from a common frequency reference source (124), to provide the necessary clock signals throughout the system.

### TECHNICAL FIELD OF THE INVENTION

The present invention relates generally to the field of automated semiconductor device testing and, more particularly, to apparatus and methods for reliably sampling high edge rate analog test signals in a time-independent manner.

### BACKGROUND OF THE INVENTION

The continual demand for enhanced performance in electronic devices—particularly with respect to integrated circuits operating therein—has resulted in dramatic alterations of semiconductor device properties and behaviors. Efforts are continually made to reduce the size of most substructures within semiconductor devices, even while performance demands on those devices are continually increased. A number of improvements and innovations in fabrication processing, material composition, and layout of the active circuit levels of a semiconductor device have resulted in very high-density circuit designs that operate at very high performance levels. The increasing circuit density and performance levels of such cutting-edge devices generate a number of challenges to commercial semiconductor manufacturing processes.

For example, high-density, high-performance semiconductor devices often strain or exceed the functional limits of automated test equipment (ATE) utilized in many commercial semiconductor production processes. In most cases, semiconductor components within a high volume ATE apparatus are, at least, several years old. As such, parametric performance levels (e.g., signal frequency) of certain ATE functions are limited or fixed at legacy values. The same ATE apparatus, however, may be routinely tasked with testing devices that operate at cutting-edge performance levels, well beyond its own. For certain testing needs, this basic disconnect between tester performance and the performance of a device under test (DUT) can cause a number of testing irregularities or errors.

Consider, for example, issues that arise in testing devices that implement high-speed serial interface protocols (e.g., Ethernet, USB). Commonly, signal rise and fall times (i.e., edge rates) are a critical parameter in the testing and characterization of a semiconductor device implementing a high-speed serial interface. As the speed of such interface devices increase, their edge rates decrease. Correspondingly, accurate testing and characterization of such devices requires increasingly fine signal sampling resolution. Unfortunately, even the newest and most advanced ATE often lacks the degree of resolution necessary to reliably test at such advanced performance levels. Furthermore, full and complete testing or characterization often requires evaluation of extended-length signals—such as pseudo-random patterns—that can commonly run the equivalent of hundreds or thousands of bits. Thus, substantial signal value retention (i.e., bandwidth) is required for accurate testing. Unfortunately, even advanced ATE systems often lack the necessary bandwidth to successfully test at such levels.

Such incongruities between DUT and ATE performance levels can significantly impact the progress or efficiency of device testing or characterization. Accurate test data, if even obtainable, may take a long time to compile. More daunting problems may arise from erroneous data introduced into device testing or characterization. For example, accurate testing of a given interface device may require a signal resolution window of 2 ns, whereas available ATE may only provide a resolution window of 4 ns. The ATE may therefore not be able to accurately assess boundaries of the 2 ns window—whether only a portion, or all, of the 2 ns window is subsumed within a given 4 ns window. As a result, pass or fail data for the device may have an unusually high probability of error—potentially decreasing device yield or increasing the likelihood of end-equipment failures.

Given such issues and concerns, a number of conventional schemes have attempted to supplement the signal characterization capabilities of ATE. Commonly, such schemes utilize some form of a sample and hold function to effectively slow down a portion of a signal. Once the sample and hold function has operated on a signal, the ATE is usually able to process the slowed version of the signal. Although conventional sample and hold schemes are somewhat helpful in this regard, they also introduce certain performance issues that require designers to make a number of tradeoffs.

Most conventional sample and hold devices utilize capacitors as temporary signal storage means. There are some sample and hold devices that are capable of handling signals having very fast edge rates with a high degree of precision. Due to their precision, however, these devices tend to be relatively expensive and of limited usefulness for commercial ATE systems. Furthermore, these high-performance sample and hold devices usually rely upon very small capacitors as signal storage means, in order to achieve elevated performance levels. Unfortunately, such small capacitors have relatively high droop rates—i.e., signal charges stored thereon begin to dissipate severely and rapidly. Severe droop rates limit the usefulness of such devices in ATE applications requiring extended signal evaluation.

Other, less-expensive conventional sample and hold devices are available. Although these devices tend to have lower droop rates than high-performance versions, they are typically still not robust enough for extended signal evaluation. They generally lack the resolution or retention necessary for full and accurate testing in high-performance applications.

As a result, there is a need for a system that provides accurate and stable signal sampling while obviating the effects of capacitive signal dissipation—thereby providing time-independent signal sampling that overcomes incongruities between signal rate capabilities of DUTs and ATE—in an easy, efficient and cost-effective manner.

### SUMMARY OF THE INVENTION

The present invention provides a versatile system, comprising a number of apparatus and methods, for accurate and stable signal sampling that overcomes incongruities between signal rate capabilities of DUTs and ATE. The system of the present invention obviates instabilities due to capacitive signal dissipation—providing time-independent signal sampling. The system of the present invention utilizes commercially viable components that are readily adaptable to a number of design and fabrication processes—overcoming certain limitations associated with conventional approaches in an easy, efficient and cost-effective manner.

Specifically, the system of the present invention provides analog-to-analog sampling, using analog-to-digital-to-analog (A/D/A) conversion. The system of the present invention further provides sample decimation. The system of the present invention applies A/D/A conversion in conjunction with sample decimation to analyze or sample a desired test signal. The A/D/A conversion of the present invention provides a stable, discrete sample value that may be held indefinitely without degradation. The sample decimation of the present invention provides a desired sampling resolution and performance optimization, regardless of a desired test signal's period length. The system of the present invention thus provides test signal sampling of a desired resolution that is time-independent—obviating performance incongruities between an advanced DUT and an ATE system.

More specifically, certain embodiments of the present invention provide a device testing system that overcomes certain performance incongruities between a high-speed device and commercial ATE. The system of the present invention provides an analog-to-analog sampler, having a clock input. The analog-to-analog sampler receives a first analog test signal from the high-speed device, and converts it into a second analog test signal at a desired rate, utilizing an analog-to-digital-to-analog conversion function and a decimation function. The ATE system houses an analog capture component. The analog capture component has a clock input, and receives the second analog test signal for conversion into digital format. A series of clock signals are generated from a common frequency reference source, to provide the necessary clock signals throughout the system.

Other embodiments of the present invention provide a method of digitizing a high-speed analog test signal at a desired rate. This method includes providing a frequency reference source, and generating a first, second and third clock signal from the frequency source. A device generates, responsive to the first clock signal, a high-speed analog test signal, having a unit test period. A high-bandwidth analog-to-digital converter receives the high-speed analog signal and converts it to a first digital signal, responsive to the second clock signal. A decimation function generates a decimation clock signal from the second clock signal. A digital-to-analog converter samples the digital signal, responsive to the decimation clock signal, and generates an analog sample signal therefrom. A digitizer receives and digitizes the analog sample signal responsive to the third clock signal.

Certain embodiments of the present invention further provide an analog-to-analog signal sampler. A high-bandwidth analog-to-digital converter receives a first analog signal, and converts it to a digital signal responsive to a first clock signal. A decimation function receives the first clock signal and generates therefrom a decimation clock signal of a desired frequency. A digital-to-analog converter, coupled to the high-bandwidth analog-to-digital converter, receives the digital signal and converts it into a second analog signal responsive to the decimation clock.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 provides an illustration depicting one embodiment of an ATE system according to the present invention; and

FIG. 2 provides a timing diagram depicting an illustrative performance of a portion of the system of FIG. 1.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The present invention is hereafter illustratively described in conjunction with the automated testing of high signal edge-rate device technologies. The specific embodiments discussed herein are, however, merely demonstrative of specific ways to make and use the invention and do not limit the scope of the invention.

The present invention comprehends a number of issues arising in certain conventional ATE testing applications. Typically, ATE utilized in commercial semiconductor manufacturing processes lacks instrumentation capable of directly capturing or characterizing a number of high-speed signals. Generally, such ATE systems receive—as an input—a signal transmitted from a DUT. Certain problems arise when the signal originates from a high-speed interface device, such as a 10/100 Ethernet or USB 2.0 device. In order to characterize and process an input signal, ATE directs the input signal through some form of digitizer. In conventional systems, as previously described, these digitizers frequently lack sufficient speed or bandwidth to digitize a received high-speed signal in real time.

High-speed serial interfaces—such as 10/100 Ethernet or USB 2.0—typically have very stringent specifications on the shape of a transmitter waveform, and thus require testing at very high effective sampling rates in order to achieve sufficient resolution for measuring critical performance parameters—such as rise or fall times (i.e., edge rates), overshoot, or undershoot. Thus, for testing purposes, the resolution afforded by conventional ATE digitizers is often insufficient for determining whether a DUT is compliant or meets specifications. Furthermore, such high-speed devices often require effective sampling rates that reach into the hundreds of gigahertz—rendering techniques that might otherwise compensate for slower ATE (e.g., Nyquist sampling) ineffectual.

Unlike actual end-equipment use, however, testing applications afford certain conveniences that can be exploited to overcome some limitations of conventional ATE systems. For example, transmitter devices can be forced to generate repetitive waveforms. This can be exploited utilizing, for example, under-sampling techniques in order to compensate for insufficient bandwidth in ATE components (e.g., digitizer). Unfortunately, however, the complexity and speed of certain high-speed serial interfaces can require the use of extremely long pseudo-random waveforms that can still overwhelm ATE capacity—even where under-sampling techniques are employed.

Generally, conventional under-sampling techniques rely on a sample and hold device. As previously described, significant problems arise from sample and hold droop. Since a sampling capacitor used to accurately capture a DUT waveform is usually very small, device parasitics can cause a very rapid dissipation of capacitor charge and, hence, a droop in captured voltage. Sample and hold devices that begin to approach the bandwidth and speed necessary to process long pseudo-random waveforms utilize extremely small capacitors—resulting in drastic and almost immediate droop. Even where—as in some high-bandwidth sample and hold components—a second sample and hold having lower bandwidth is cascaded in an attempt to reduce droop, a significant dissipation of a signal charge may still occur.

Furthermore, under-sampling of long data sequences requires low sample and hold clock rates. This further contributes to and results in droop problems. A sample and hold clock rate in such an application cannot simply be set to an integer multiple of the test signal period, since the sample and hold output is analog. Shuffling of data in such a manner would require a tremendous bandwidth increase—rendering the system extremely inefficient or inoperable.

Comprehending this, the present invention addresses incongruities between signal rate capabilities of disparate technology components—particularly high edge-rate DUTs and commercial ATE—and issues related thereto. The present invention provides a versatile system, comprising a number of apparatus and methods, for accurate and stable signal sampling that overcomes such incongruities. The system of the present invention obviates sampling instabilities otherwise commonly associated with capacitive signal dissipation, and thereby provides time-independent signal sampling. The system of the present invention further utilizes commercially viable technology and methods that are readily adaptable to a number of design and fabrication processes.

Specifically, the system of the present invention provides analog-to-analog sampling in a manner that obviates interdependence of input and output signal rates. In certain embodiments of the present invention, the analog-to-analog sampling is provided by analog-to-digital-to-analog (A/D/A) conversion. The A/D/A conversion of the present invention renders stable, discrete signal sample values that may be held indefinitely without degradation. A/D/A conversion according to the present invention may be implemented in a number of economical manners (e.g., using off-the-shelf (OTS) parts, integrating appropriate circuitry into a custom or semi-custom semiconductor device).

The system of the present invention further provides signal sample decimation. The signal sample decimation of the present invention provides a desired signal sampling resolution, regardless of the repetition length (or period) of the desired test signal. The system of the present invention applies analog-to-analog sampling in conjunction with sample decimation to analyze or sample a desired test signal. The system of the present invention thus provides test signal sampling of a desired resolution that is time-independent—obviating performance incongruities between an advanced DUT and an ATE system.

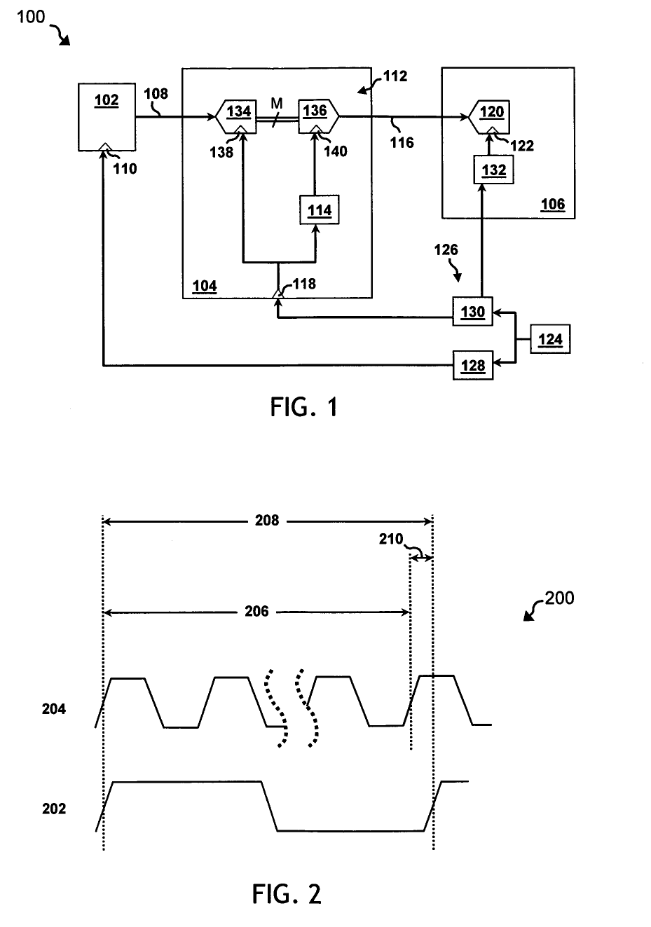

Certain features and operations of the present invention are described in greater detail with reference now to FIG. 1, which depicts an illustrative embodiment of a testing system 100 according to the present invention. System 100 comprises a DUT 102, an analog-to-analog sampler 104, and ATE system 106. DUT 102 comprises a high-speed serial interface device (e.g., 10/100 Ethernet device, USB 2.0 device). DUT 102 transmits an analog test signal 108 responsive, directly or indirectly, to a clock input 110. Sampler 104 comprises an analog-to-digital-to-analog (A/D/A) conversion function 112 and a decimation function 114. Sampler 104 receives test signal 108 as an input, and outputs a corresponding analog sample signal 116. A/D/A function 112 and decimation function 114 operate responsive to a clock input 118.

System 106 comprises an analog capture component 120 that receives, as its test input signal, the sample signal 116 output from sampler 104, and converts that signal into a format (i.e., digital) compatible with a variety of ATE testing and evaluation protocols. In most commercial ATE systems, component 120 comprises a digitizer disposed within the ATE. In alternative embodiments, component 120 may comprise a discrete portion of a digitizer. In still other embodiments, component 120 may comprise an analog capture device or instrument separated from but operatively associated with a digitizer. Other combinations and variations are comprehended by the present invention, also. Component 120 further comprises a clock signal input 122.

System 100 comprises a frequency reference source 124, from which system clock signals are sourced or calibrated. Source 124 comprises any suitable highly accurate and stable clock signal source (e.g., crystal oscillator, PLL). One or more clocks or clock signals 126 are generated from source 124. In certain embodiments, a single clock signal 126 may be provided to clock inputs of DUT 102, sampler 104, and component 120. In other embodiments, such as the one depicted in FIG. 1, some or all components within system 100 may be provided with separate clocks 126.

For example, certain test systems or configurations may require a separate clock signal 126 for DUT 102. As shown in FIG. 1, clock input 110 is coupled to an independent DUT clock signal 128. A separate sampling clock signal 130 is coupled to inputs 118 and 122. ATE 106 may, optionally, comprise a decimation function 132, interposed between clock signal 130 and clock input 122. In such an embodiment, clock input 122 receives clock signal 130 as modified by function 132.

In the embodiment depicted in FIG. 1, sampling function 112 comprises a high-bandwidth, M-bit analog-to-digital converter (ADC) 134, and a high-bandwidth, M-bit digital-to-analog converter (DAC) 136, operatively coupled together. In the embodiment depicted in FIG. 1, converters 134 and 136 comprise individual, off-the-shelf (OTS) semiconductor converter devices, disposed upon a printed circuit board or some similarly suitable operation platform. In alternative embodiments, however, converters 134 and 136 may comprise converter portions of other independent OTS semiconductor devices, converter functions implemented within a single OTS or custom semiconductor device, converter functions implemented using software in conjunction with some processing hardware, or various combinations thereof. Converter 134 comprises a clock input 138 that receives a clock signal directly from input 118. Converter 136 comprises a clock input 140 that receives a clock signal from input 118, as modified by function 114. As described below, function 114 transforms the clock signal from input 118 into a decimation clock signal of a desired frequency. This decimation clock signal is then provided to converter 136, such that it cycles only at a desired interval.

Functionally, sampler 104 provides M-bit A/D/A conversion in a manner that eliminates issues otherwise associated with signal droop, since ADC 134 immediately converts analog signal 108 into a digital form that may, if necessary, be held indefinitely. In the embodiment depicted in FIG. 1, function 114 comprises a divide-by-N counter (Div N₁). Counter 114 is interposed between clock input 118 and input 140 of DAC 136 to provide decimation of data from ADC 134—freeing ADC 134 to operate at its optimal specified frequency range. This independent clocking may be optional or necessary, depending upon the architecture or operation of the converter utilized.

For example, certain pipeline and sub-ranging converters may require the independent clocking of the present invention—since droop issues can arise if they are clocked too slowly. Other converter types—while not requiring the independent clocking of the present invention to avoid droop—may operate more efficiently where this independent clocking is utilized. Regardless of what type of ADC is used, therefore, performance of ADC 134 may be optimized to eliminate droop issues.

During a given test operation for DUT 102, clock signal 128 is set to a corresponding desired or required frequency and provided to DUT 102 through its input 110. For the given test operation, DUT 102 is configured to output a pre-defined analog output signal 108. Analog output signal 108 has a pre-defined unit test period (P_{TEST}). A wide range of signals, having test periods of greatly varying lengths, may be provided in accordance with the present invention.

Clock signal 130 is set to a frequency having a period—the capture period (P_{CAPTURE})—that is an integer division (preferably prime) of P_{TEST}, plus or minus a small factor. This small factor is the sample period (P_{SAMP})—also referred to as beat frequency period, or just beat frequency—and it determines the effective resolution and sampling rate of system 100. Reference frequency source 124 is provided to clocks 128 and 130 to ensure precision and long-term stability of the sample period (or beat frequency period)—providing reliable, coherent sampling. Referring now to FIG. 2, timing diagram 200 further describes, and depicts an illustrative example of, the relationship between signal 108 and clock 130.

Diagram 200 comprises a first signal trace 202 and a second signal trace 204. Trace 202 represents clock signal 130, while trace 204 represents signal 108. Interval 206 represents some integer multiple of the unit test period (N*P_{TEST}). Interval 208 represents the capture period (P_{CAPTURE}). Interval 210 represents the sample period (P_{SAMP}). Interval 208 is equal to:
(N*P_{TEST})+(P_{SAMP}). (1)
Utilizing this relationship, sampler 104 may be set to sample signal 108 at a desired sampling resolution, regardless of performance incongruities between DUT 102 and sampler 104 (i.e., ADC 134). Specifically, clock 130 may be set to frequency that provides a desired sampling period in relation to the unit test period of signal 108.

For example, in an embodiment where signal 108 has a unit test period of 80 ns, a sampling period of 0.05 ns is desired, and the rate of signal 108 exceeds the performance of ADC 134 by a factor of Z, system 100 may be configured to sample signal 108 in 0.05 ns increments by setting clock 130 to a frequency having a period of ((Z*80)+0.05) ns. Similarly, if ADC 134 capable of performance at the rate of signal 108 (i.e., Z=1), then clock 130 may be set to a frequency having a period of 80.05 ns. System 100 thus provides coherent under-sampling of signal 108, regardless of the relative performance levels of DUT 102 and sampler 104.

In addition to selective provision of clock 130, system 100 provides further optimization of sampling rates through decimation function 114. Function 114 transforms a clock signal from input 118 into a decimation clock signal of a desired frequency. This decimation clock signal is then provided to converter 136, such that it cycles only at a desired interval. In system 100, function 114 comprises a divide-by-N counter (Div N₁). This divide-by-N counter may be implemented in any suitable format—utilizing, for example, a standard or custom semiconductor device, or some portion thereof, or some counter function in software format, running on a processor. In alternative embodiments, function 114 may comprise some other fixed or adjustable clocking mechanism that provides decimation in accordance with the present invention.

As previously described, ADC 134 may—depending upon its specific architecture—be operated at some minimum frequency in order to avoid droop. Within system 100, however, DAC 136 may be operated, for a number of reasons, at a lower frequency than ADC 134. In certain embodiments, for example, utilizing a lower frequency DAC 136 may result in a more cost effective system. In other embodiments, a lower frequency DAC 136 may be required to render sample signal 116 more compatible with the performance capabilities of system 106.

Once the desired or required performance level of DAC 136 is determined, the N value for function 114 is set to deliver a corresponding decimation clock signal to input 140. For example, in an embodiment where ADC 134 must run at 10 MHz and DAC 136 must run at 1 MHz, function 114 is set with an N value of 10. DAC 136 thus cycles at 1/10^{th} the rate of ADC 134—utilizing only every 10^{th} sample received from ADC 134. In similar fashion, function 114 may be set to clock DAC 136 at any desired or required rate within the performance range thereof.

Clock 130 is also coupled, directly or indirectly, to analog capture component 120. Similar to ADC 134, component 120 may have an optimal or required operational frequency. In embodiments where operation of component 120 is compatible with clock signal 130, input 122 may be directly coupled thereto. In a number of embodiments, however, the operational frequency of component 120 may be substantially lower than that of clock 130. In such embodiments, function 132 may be provided, between clock 130 and input 122, to provide decimation of clock signal 130. In system 100, function 132 comprises a divide-by-N counter (Div N₂), interposed between clock 130 and input 122. Function 132 operates in a manner similar to function 114, freeing component 120 to operate at its optimal frequency. In alternative embodiments, an additional independent clock 126 may be provided to clock component 120 at its required rate.

Depending upon the specific configuration of system 100, the relative position of its constituent components may be varied greatly to optimize performance or efficiency. If DUT 102 and system 106 are collocated in immediate proximity, sampler 104 may be implemented directly within system 106. If DUT 102 and system 106 are not in close physical proximity, however, sampler 104 may—for example—be implemented on a device interface board (DIB), close to DUT 102, in order to obviate certain distortion problems (e.g., transmission line, lumped load) between DUT 102 and system 106. In other embodiments, the constituent members of system 100 may be implemented in conjunction with conventional sample and hold devices. For example, a high-bandwidth sample and hold device may be interposed between DUT 102 and sampler 104 to accommodate arbitrarily high test signal bandwidths with no droop-related problems, and regardless of DUT unit test period length. Other similar variations and combinations are comprehended by the present invention.

Thus, utilizing the present invention, timing interdependencies of disparate signal sampling functions or components are obviated. According to the present invention, an ATE system may be adapted to optimize sampling rates for each component independently. The present invention thus provides accurate and stable signal under-sampling in a highly versatile manner that greatly simplifies otherwise complex ATE applications. The structures and methods of the present invention provide for a number of implementations that may be optimized for performance, efficiency or cost. The analog-to-digital-to-analog (A/D/A) conversion of the present invention is readily adapted to a wide range of devices or systems, as are the sampling rate optimization techniques.

The embodiments and examples set forth herein are therefore presented to best explain the present invention and its practical application, and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. As stated throughout, many modifications and variations are possible in light of the above teaching without departing from the spirit and scope of the following claims.

What is claimed is:

1. A testing system comprising:
an analog-to-analog sampling component, having a clock input, adapted to receive a first analog test signal from a device under test and to convert the first analog test signal into a second analog test signal at a desired rate;
an automated test equipment system, adapted to receive the second analog test signal;
an analog capture component disposed within the automated test equipment system, having a clock input, adapted to receive the second analog test signal and convert it into digital format;
a frequency reference source;
a first clock signal, generated from the frequency reference source, coupled to the device under test;
a second clock signal, generated from the frequency reference source, coupled to the clock input of the analog-to-analog sampling component; and
a third clock signal, generated from the frequency reference source, coupled to the clock input of the analog capture component.

2. The testing system of claim 1, wherein the analog-to-analog sampling component comprises an analog-to-digital-to-analog conversion function.

3. The testing system of claim 2, wherein the analog-to-analog sampling component comprises a decimation function, adapted to receive the second clock signal from the clock input of the analog-to-analog sampling component and to generate a first decimation clock signal.

4. The testing system of claim 1, wherein the analog capture component comprises a digitizer.

5. The testing system of claim 3, wherein the analog-to-digital-to-analog conversion function support structure comprises:
a high-bandwidth analog-to-digital converter, adapted to receive the first analog test signal, and operable responsive to second clock signal; and
a digital-to-analog converter, operatively coupled to the high-bandwidth analog-to-digital converter, adapted to output the second analog test signal responsive to the first decimation clock signal.

6. The testing system of claim 3, wherein the decimation function comprises a divide-by-N counter.

7. The testing system of claim 5, wherein the high-bandwidth analog-to-digital converter is a discrete component.

8. The testing system of claim 5, wherein the digital-to-analog converter is a discrete component.

9. The testing system of claim 1, further comprising a high-bandwidth sample and hold device interposed between the device under test and the analog-to-analog sampling component.

10. The testing system of claim 1, wherein a single clock provides the second and third clock signals.

11. A method of digitizing a high-speed analog test signal at a desired rate, the method comprising the steps of:
providing a frequency reference source;
generating a first, second and third clock signal from the frequency source;
providing a device generating a high-speed analog test signal, having a unit test period, responsive to the first clock signal;
providing a high-bandwidth analog-to-digital converter, receiving the high-speed analog signal, and converting it to a first digital signal, responsive to the second clock signal;
providing a decimation function generating a decimation clock signal from the second clock signal;
providing a digital-to-analog converter, sampling the digital signal, responsive to the decimation clock signal, and generating an analog sample signal therefrom; and
providing a digitizer receiving and digitizing the analog sample signal responsive to the third clock signal.

12. The method of claim 11, wherein the step of generating a first, second and third clock signal further comprises:
determining a desired sample period; and
generating the second clock signal such that the period of the first digital signal is equal to the desired sample period plus an integer multiple of the unit test period.

13. The method of claim 11, wherein the step of providing a frequency reference source comprises providing a crystal oscillator.

14. The method of claim 11, wherein the step of providing a decimation function generating a decimation clock signal further comprises providing a divide-by-N counter.

15. The method of claim 11, wherein the step of providing a decimation function generating a decimation clock signal further comprises providing a decimation function generating a decimation clock signal that results in an analog sample signal of a desired frequency.

16. The method of claim 12, wherein the step of generating the second clock signal further comprises generating the second clock signal such that the period of the first digital signal is equal to the desired sample period plus a prime integer multiple of the unit test period.

17. An analog-to-analog signal sampler comprising:
a high-bandwidth analog-to-digital converter, adapted to receive a first analog signal and convert the first analog signal to a digital signal responsive to a first clock signal;
a decimation function, adapted to receive the first clock signal and to generate a decimation clock signal of a desired frequency; and
a digital-to-analog converter, coupled to the high-bandwidth analog-to-digital converter to receive the digital signal and adapted to convert the digital signal into a second analog signal responsive to the decimation clock.

18. The sampler of claim 17, wherein the decimation function comprises a divide-by-N counter.

19. The sampler of claim 17, wherein the high-bandwidth analog-to-digital converter is a discrete component.

20. The sampler of claim 17, wherein the digital-to-analog converter is a discrete component.
